(19) United States
(12) Patent Application Publication
(10) Pub. No.: US 2005/0275098 A1
(43) Pub. Date: Dec. 15, 2005

(54) Lead-free conductive jointing bump

(75) Inventor: Jeng-Da Wu, Kaohsiung City (TW)

Correspondence Address: GENESIS/GENUS LAW GROUP, 12760 HIGH BLUFF DRIVE, SUITE 300, SAN DIEGO, CA, 92130, US

(73) Assignee: Advance Semiconductor Engineering Inc.

(21) Appl. No.: 11/151,755

(22) Filed: Jun. 14, 2005

(30) Foreign Application Priority Data
Jun. 15, 2004 (TW) 93117184

(51) Int. Cl. H01L 23/48; H01L 23/52; H01L 29/40

(52) U.S. Cl. 257/737

(57) ABSTRACT

A conductive jointing structure that is applied on a chip with multitude of connection pads has a first conductive structure and a second conductive structure. The first conductive structure is allocated on one of the contact pads. The second conductive structure made of lead-free based material is consisted of multitude of stacked portions with respectively different modulus. The portion contacting the first conductive structure is with small modulus, while the portion away from the first conductive structure is with large modulus.

### RELATED DOCUMENTS

Foreign priority is claimed under 35 USC §119 based on Taiwan Patent Application Serial No.: 093117184 filed on Jun. 15, 2004 which is incorporated herein by reference in its entirety.

### BACKGROUND OF THE INVENTION

1. Field of the Invention

The invention relates generally to a structure of conductive bump or solder for jointing a semiconductor device and a conductive substrate. In particular, the invention relates to a structure of conductive bump or solder made of lead-free.

2. Description of the Prior Art

In the development of integrated circuit technology, a conductive structure is used for jointing a semiconductor device such as a chip and a conductive substrate such as an organic or ceramic substrate for package. As protection of environment is under the consideration, the material of the conductive structure changes from solder alloy to lead-free material, such as tin and silver alloy.

It can not be denied that there are some issues in company with the tin and silver alloy for the jointing conductive structure. For example, lead-free material is subject to high temperature or thermal cycle, thermal mechanistic, or metal fatigue. On the other hand, an under bump metallurgy layer, the semiconductor device, and the conductive substrate, which affix or connect the lead-free conductive structure, are in close relation to it. Owing to the high modulus of the lead-free material associated with the structures aforementioned, the cracking issue in or between the conductive bump or solder may not be neglected.

### SUMMARY OF THE INVENTION

Accordingly, a bump or solder with multi layers stacked each another is provided. The cracking issue in or on the bump or solder is reduced by varying the compositions of the layers.

For improving reliability between a conductive structure of lead-free material and the under bump metallurgy layer, a bump or solder of stacked structure is provided to have a portion of smaller modulus affixed and contacted the under bump metallurgy layer below for improving the reliability.

For a substrate in connection with one or more conductive solders or bumps, a bump or solder of stacked structure is provided to have a portion of larger modulus affixed and contacted the substrate for improving the reliability.

In accordance with an embodiment of the present invention, a conductive jointing structure is provided applicable for a wafer. There are multitudes of chips in the wafer, each which has multitudes of conductive structures. Each conductive structure includes two conductive sub-structures. The first conductive sub-structure is disposed on a connection pad of one chip. The second conductive sub-structure is made of lead-free material basically and made up of stacked layers with various modului respectively. The region contacting or near the first conductive sub-structure has a relatively small modulus, while the region far away from the first conductive sub-structure has a relatively larger modulus.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic cross-sectional diagram illustrating a conductive structure in accordance with the present invention; and

FIGS. 2A to 2D are schematic cross-sectional diagrams illustrating the process for the conductive structure in accordance with the present invention.

### DESCRIPTION OF THE PREFERRED EMBODIMENTS

Before describing the invention in detail, a brief discussion of some underlying concepts will first be provided to facilitate a complete understanding of the invention.

FIG. 1 is a schematic cross-sectional diagram illustrating an embodiment in accordance with the present invention. Shown in FIG. 1, a wafer includes multitudes of chip units 10 each which has one or more conductive pads 12, a passivation layer 14, one or more conductive structures 16 (only one shown in the figure) and 18. In one embodiment, each chip unit 10, which is cut down from a silicon wafer, has an active surface attaching the conductive pad 12 and the passivation layer 14. The conductive pad 12 is a bonding pad or a connection pad, such as an aluminum pad. The passivation layer 14 covers over the active surfaces of the chip units 10 and the partial surface of the conductive pad 12 for protecting the active surfaces of the chip units 10.

Furthermore, in the embodiment, the conductive structure 16, such as an under-bump-metallurgy structure, is a multi-layer structure affixing and connecting the conductive pad 12 below and the conductive structure 18 above. Typically, the conductive structure 16 configured for adhesion, barrier and wetting may be variable dependent on the conductive pad 12 below and the conductive structure 18 above. For example, the portion of the conductive structure 16 contacting the conductive pad 12 below is made of Ti (titanium), Cr, or TiW layer, while other portion contacting the conductive structure 18 above Cu or Ni layer. It is understandable that since the conductive structure 18 is basically made of lead-free material the conductive structure 16 is made of the material compatible and further provides the functions aforementioned.

Furthermore, the conductive structure 18 is configured for jointing and supporting the chip unit 10 and the conductive substrate 25. In the embodiment, the conductive structure 18 is made of lead-free material and is of multiple layers stacked each another for the sake of preventing the conductive structure 18 from cracking owing to large modulus. As the multiple layers so called, there are two or more layers of different modului respectively. Alternatively, the multiple layers are of distinguishable compositions respectively. Furthermore, the so-called each stacked layer is dependent on how far from the conductive structure 16 it is. Shown in FIG. 1, the conductive structure 18 is made of bottom region 20, middle region 22, and top region 24, in which the bottom region 20 contacts and connects the conductive structure 16, the top region 24 is far from the conductive structure 16 or contacts the conductive substrate 25, and the middle region 22 is interlaid between the bottom region 20 and the top region 24.

In the embodiment, the bottom region 20, which has a modulus lower than that of the middle region 22, is made of a tin, silver and copper alloy basically, which is in weight percentage, x1% silver, 0<=x1<2; and y1% copper, 0.5<y1<=1.0; and remainder tin, and preferable SnAgCu alloy (Vickers Hardness=14) or Sn0.7Cu alloy. Moreover, the middle region 22 affixes and connects the bottom region 20 below and the top region 24 above, which is also made of a tin, silver and copper alloy basically: in weight percentage, x2% silver, 3<=x2<4; and y2% copper, 02<y2<=0.5; and remainder tin, and preferable Sn4Ag0.5Cu alloy (Vickers Hardness=18). The top region 24 affixes and connects the 25, which is made of Sn3.5Ag alloy. It is noted that the compositions in the multi layers of the conductive structure 18, from bottom to top, the weight percentage of silver increases, while the weight percentage of copper decreases, oppositely. That is, in the embodiment, the bottom region 20 of relatively low modulus is got by either decreasing the weight percentage of silver or increasing the weight percentage of copper, or both. Hence, the silver amount in the bottom region 20 is less than those both in the middle region 22 and in the top region 24. On the other hand, the top region 24 of relatively high modulus is got by either increasing the weight percentage of silver or decreasing the weight percentage of copper, or both. Hence, the copper amount in the top region 24 is less than those both in the middle region 22 and in the bottom region 20.

In another embodiment, based on the modulus of the middle region 22, the moduli of both the bottom region 20 and the top region 24 are less than that of the middle region 22. Hence, compared to the middle region 22, both the bottom region 20 and the top region 24 are softer than the middle region 22. In such an embodiment, it is understandable that the softer bottom region 20 or top region 24 is got also by either decreasing the weight percentage of silver or increasing the weight percentage of copper, or both. Thus, though the whole modulus of the conductive structure 18 is reduced, the conductive structure 18 still supports the chip unit 10 and the conductive substrate 25 and further prevents the interfaces near or on the chip unit 10 or the conductive substrate 25 from cracking.

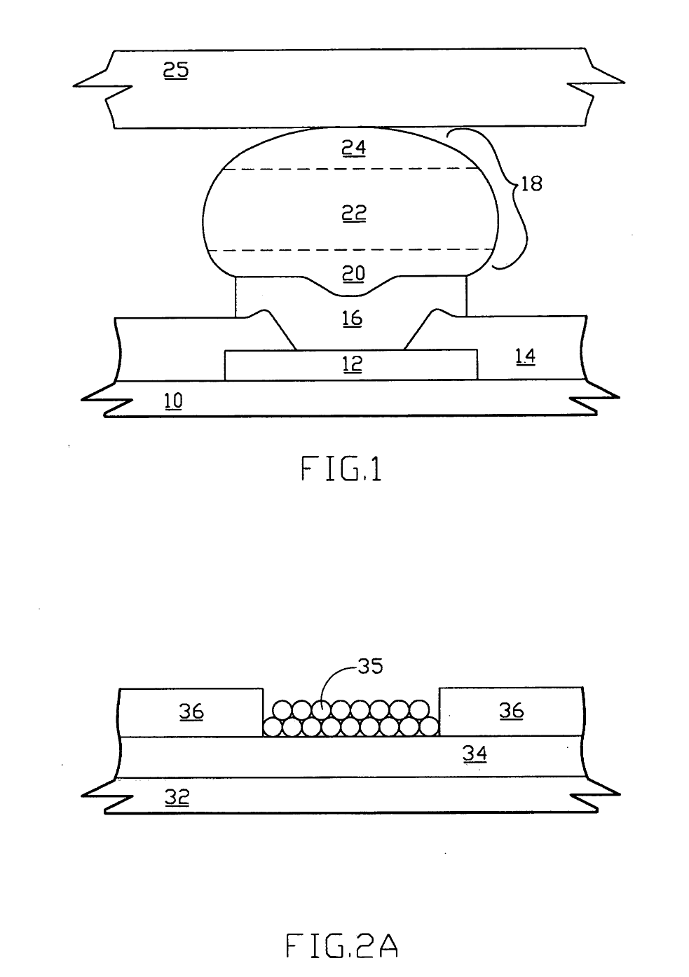

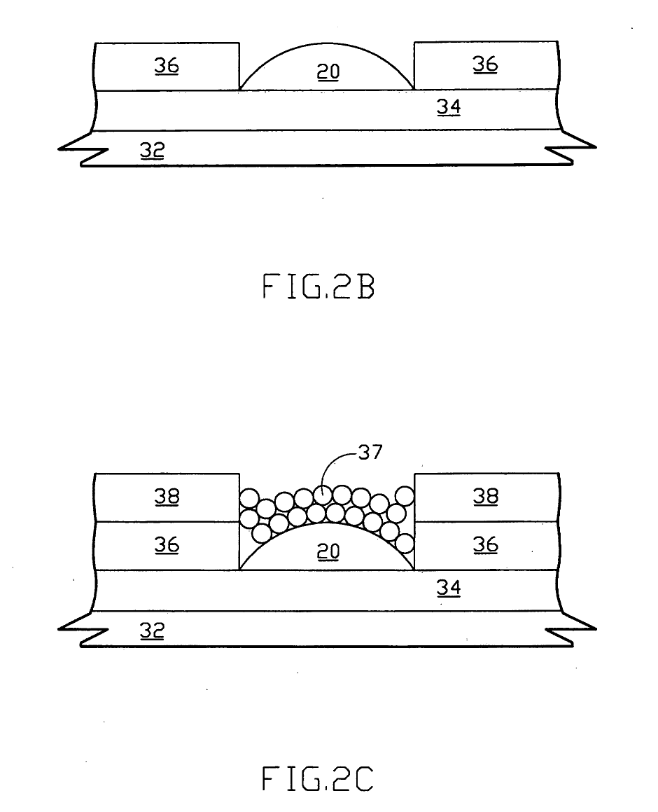

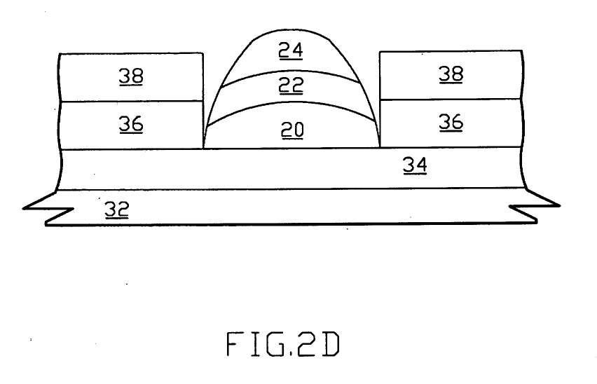

FIGS. 2A-2D are schematically cross-sectional diagrams illustrating the process form manufacturing the conductive structure 18 in accordance with the present invention. Depicted as FIG. 2A, an UBM structure 34 (shown as single layer) is formed, by any suitable methods, on the multitudes of chip units 32 of a wafer structure. A mask layer 36, such as a dry film, is formed on the UBM structure 34 and then removed to expose the partial surface of the UBM structure 34. Next, by any suitable methods, such as sputtering, a conductive material 35 for forming the bottom of the bump covers the exposed surface of the UBM structure 34. Shown in FIG. 2B, the conductive material 35 is reflowed to form the bottom region 20. Alternatively, another masking film (not shown) is formed on the surface of the bottom region 20 by sputtering after the reflowing of the conductive material 35, which is exemplary Ni film as a cap for preventing the compositions in the layers from diffusion each another. Next, another mask layer 38 is formed by any suitable methods, which has at least one opening definitely above that of the mask layer 36 for promoting the height of the subsequent formed bump. Next, conductive material 37 is sputtered into the openings and then reflowed to form the middle region 22, shown in FIG. 2C. Similarly, another conductive material is filled into the openings and then reflowed to form the top region 24, shown in FIG. 2D. The conductive structure 18 may be applied on any lead-free bump or solder for improving thermal mechanistic property, cracking expiration, and aging caused by high temperature short time HTST/EM. Furthermore, the conductive structure 18 is also applied on flip chip ball grid array for improving reliability.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

1. A system of a conductive device for connecting a chip with an active surface and a conductive substrate, the system of the conductive device comprising:
an under-bump-metallurgy structure contacted and disposed on said active surface of said chip; and
a conductive structure contacted and disposed between said under-bump-metallurgy structure and said conductive substrate, said conductive structure comprising a first portion and a second portion, wherein said first portion is attached said under-bump-metallurgy structure, and wherein a modulus of said first portion is smaller than a modulus of said second portion.

2. The system of the conductive device according to claim 1, wherein said first portion and said second portion are stacked each other to form said conductive structure.

3. The system of the conductive device according to claim 1, wherein said conductive structure further comprises a third portion between said first and said second portions, and wherein the first, second and third portions are stacked each another.

4. The system of the conductive device according to claim 3, wherein the modulus of said first portion is smaller than a modulus of said third portion.

5. The system of the conductive device according to claim 4, wherein said second portion is contacted and attached said conductive substrate, and the modulus of said second portion is larger than the modulus of said third portion.

6. The system of the conductive device according to claim 3, wherein said second portion is contacted and attached said conductive substrate, and the modulus of said second portion is smaller than the modulus of said third portion.

7. The system of the conductive device according to claim 1, wherein the first portion of said conductive structure is made of a tin, silver and copper alloy having a composition of silver less than 2%, and copper in range of 0.5-1.0% in weight percentage.

8. The system of the conductive device according to claim 7, wherein the second portion of said conductive structure is made of a tin and silver alloy having a composition of 3.5% silver in weight percentage.

9. The system of the conductive device according to claim 1, wherein said conductive structure is made of a tin, silver and copper alloy, and the weight percentage of silver in the second portion of said conductive structure is more than that in the first portion of said conductive structure.

10. The system of the conductive device according to claim 9, wherein the weight percentage of copper in the second portion of said conductive structure is less than that in the first portion of said conductive structure.
